(19) United States
(12) Patent Application Publication
(10) Pub. No.: US 2024/0250203 A1
(43) Pub. Date: Jul. 25, 2024

(54) PRODUCTION LINE FOR PRODUCING SOLAR CELL

(71) Applicant: LAPLACE RENEWABLE ENERGY TECHNOLOGY CO., LTD., Shenzhen (CN)

(72) Inventors: Jiaji LIN, Shenzhen (CN); Aisuo PANG, Shenzhen (CN); Tairong ZHU, Shenzhen (CN)

(73) Assignee: LAPLACE RENEWABLE ENERGY TECHNOLOGY CO., LTD., Shenzhen (CN)

(21) Appl. No.: 18/438,079

(22) Filed: Feb. 9, 2024

Related U.S. Application Data
(63) Continuation of application No. PCT/CN2022/131271, filed on Nov. 11, 2022.

(30) Foreign Application Priority Data
Nov. 26, 2021 (CN) 202111419221.9

(51) Int. Cl. H01L 31/20; H01L 21/677; H01L 31/18

(52) U.S. Cl. CPC H01L 31/202; H01L 21/67781; H01L 31/1804; H01L 31/1864; H01L 31/208

(57) ABSTRACT

Disclosed is a production line for producing a solar cell, including a texturing device, a heat treatment system, a phosphorus diffusion device, an etching device, a passivation system and an electrode manufacturing system. The texturing device is configured to perform a texturing process of an N-type silicon wafer, the heat treatment system is configured to perform a boron diffusion process and a LPCVD process, the phosphorus diffusion device configured to perform a phosphorus diffusion process on the N-type silicon wafer, the etching device is configured to perform an etching process of the N-type silicon wafer, the passivation system is configured to perform a passivation layer process, a front film process and a back film process of the N-type silicon wafer, and the electrode manufacturing system is configured to perform a preparation process of electrodes on two sides of the N-type silicon wafer to form a solar cell.

### CROSS-REFERENCE TO RELATED APPLICATIONS

This application is a continuation of International Application No. PCT/CN2022/131271, filed on Nov. 11, 2022, which claims priority to Chinese Patent Application No. 202111419221.9, filed on Nov. 26, 2021. The disclosures of the aforementioned applications are hereby incorporated by reference in their entireties.

### TECHNICAL FIELD

The present application relates to the field of solar cell manufacturing technologies, and for example, to a production line for producing a solar cell.

### BACKGROUND

A mainstream technology for P-type monocrystalline solar cells is a passivated emitter and rear cell (PERC) technology. The PERC technology has a simple manufacturing process and low cost. An addition of a selective emitter (SE) technology enhances conversion efficiency of cells. As efficiency of P-type cells approaches a theoretical limit, an N-type cell technology is expected to become a mainstream direction for future development. Compared to the P-type cells, N-type cells offer advantages such as higher conversion efficiency, higher bifaciality, lower temperature coefficient, no light-induced degradation, good weak light effect, and longer carrier lifetime. Since the technologies used for the N-type cells differ from the technologies used for the P-type cells, a production equipment for the N-type cells is also different from a production equipment for the P-type cells. Therefore, an equipment used for PERC production lines maynot be adapted for the N-type cells, resulting in idle PERC production line equipment and waste.

### SUMMARY

The present application provides a production line for producing a solar cell, applied to manufacture an N-type silicon wafer into a solar cell. The production line for producing the solar cell includes: a texturing device, a heat treatment system, a phosphorus diffusion device, an etching device, a passivation system and an electrode manufacturing system. The texturing device is configured to perform a texturing process of an N-type silicon wafer. The heat treatment system is configured to perform a boron diffusion process and a low pressure chemical vapor deposition (LPCVD) process of the N-type silicon wafer. The phosphorus diffusion device configured to perform a phosphorus diffusion process on the N-type silicon wafer, to dope intrinsic amorphous silicon layer on a back side of the N-type silicon wafer with phosphorus, and perform a post-oxidation treatment, so that a phosphorus-rich layer is formed on the back side of the N-type silicon wafer. The etching device is configured to perform an etching process of the N-type silicon wafer, the passivation system is configured to perform a passivation layer process, a front film process and a back film process of the N-type silicon wafer. The electrode manufacturing system is configured to perform a preparation process of electrodes on two sides of the N-type silicon wafer to form a solar cell.

### BRIEF DESCRIPTION OF THE DRAWINGS

FIG. 1 is a schematic diagram of a cell structure according to an embodiment of the present application.

FIG. 2 is a schematic flowchart of a cell preparation process according to an embodiment of the present application.

FIG. 3 is a schematic structural diagram of a production line for producing a solar cell according to an embodiment of the present application.

FIG. 4 is a schematic diagram of a texturing device according to an embodiment of the present application.

FIG. 5 is a schematic diagram of a heat treatment system according to an embodiment of the present application.

FIG. 6 is a schematic diagram of a loading and unloading system of a heat treatment system according to an embodiment of the present application.

FIG. 7 is a schematic diagram of a loading and unloading system of another heat treatment system according to another embodiment of the present application.

FIG. 8 is a schematic diagram of a loading and unloading system of another heat treatment system according to another embodiment of the present application.

FIG. 9 is a schematic diagram of a carrier in a heat treatment system according to an embodiment of the present application.

FIG. 10 is an enlarged schematic diagram of region A in FIG. 9.

FIG. 11 is a schematic diagram of a carrier conveying and purifying system and a furnace tube system of a heat treatment system according to an embodiment of the present application.

FIG. 12 is a schematic diagram of an internal structure of a carrier conveying and purifying system of a heat treatment system according to an embodiment of the present application.

FIG. 13 is a schematic diagram of a carrier carrying system of a carrier conveying and purifying system according to an embodiment of the present application.

FIG. 14 is a schematic diagram of a carrier pushing system of a carrier conveying and purifying system according to an embodiment of the present application.

FIG. 15 is a schematic diagram of a transmission system of a carrier conveying and purifying system according to an embodiment of the present application.

FIG. 16 is a schematic diagram of an internal structure of a furnace tube system of a heat treatment system according to an embodiment of the present application.

FIG. 17 is a schematic diagram of a laser doping device according to an embodiment of the present application.

FIG. 18 is a schematic diagram of an oxidation system according to an embodiment of the present application.

FIG. 19 is a schematic diagram of an etching device according to an embodiment of the present application.

FIG. 20 is a schematic diagram of a phosphorus diffusion device according to an embodiment of the present application.

FIG. 21 is a schematic diagram of a passivation system according to an embodiment of the present application.

FIG. 22 is a schematic diagram of an electrode manufacturing system according to an embodiment of the present application.

### DETAILED DESCRIPTION OF THE EMBODIMENTS

Implementations of the present application are illustrated below through specific embodiments.

Illustrations provided in the following embodiments only illustrate basic concept of the present application in a schematic manner. The illustrations only show components related to the present application and are not drawn based on number, shape, and size of the components during an actual implementation. Type, quantity, and proportion of each component during the actual implementation may be arbitrarily changed, and component layout type thereof may alternatively be more complex.

All directional indications (such as up, down, left, right, front, back, horizontal, lateral, and longitudinal.) in the embodiments of the present application are only used to explain relative position relationship, motion situation, and the like between multiple components in a specific posture. If the specific posture changes, the directional indication alternatively changes accordingly.

The “connection” mentioned in the present embodiment may be a physical connection, or may be a process connection. For example, a connection between a first device and a second device may be understood as using a robotic arm to transport a product processed by the first device to the second device for further processing.

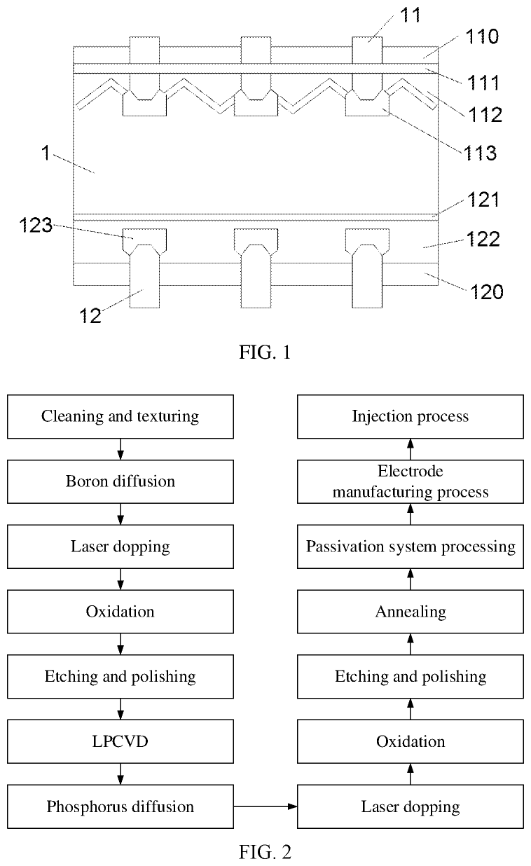

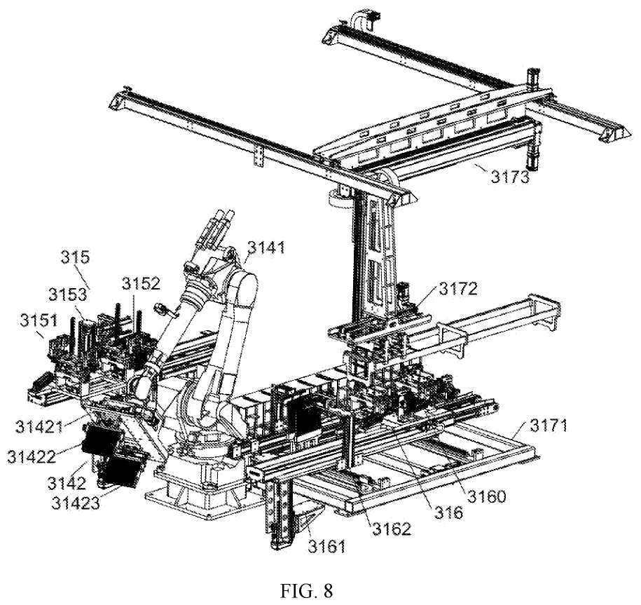

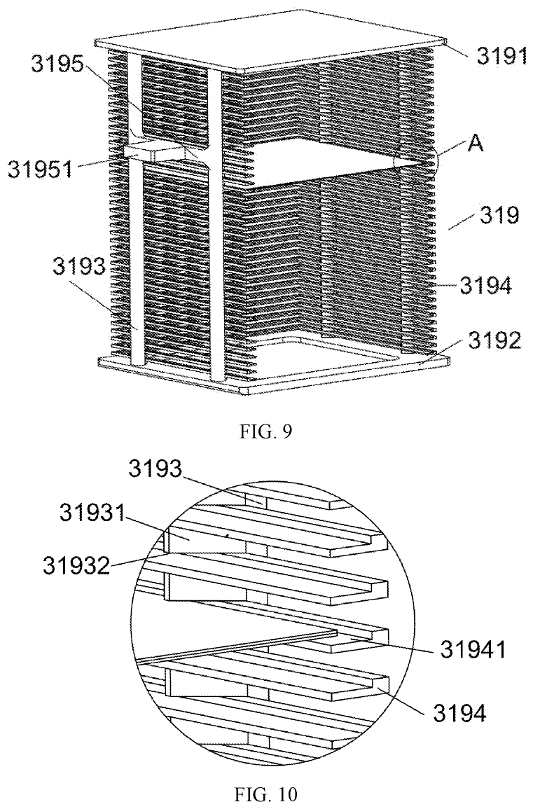

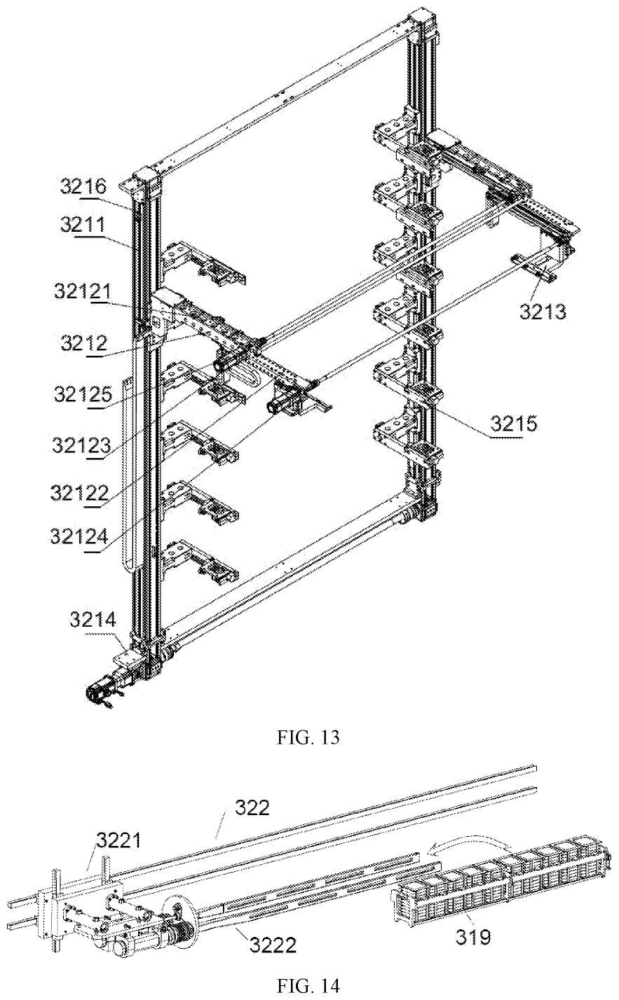

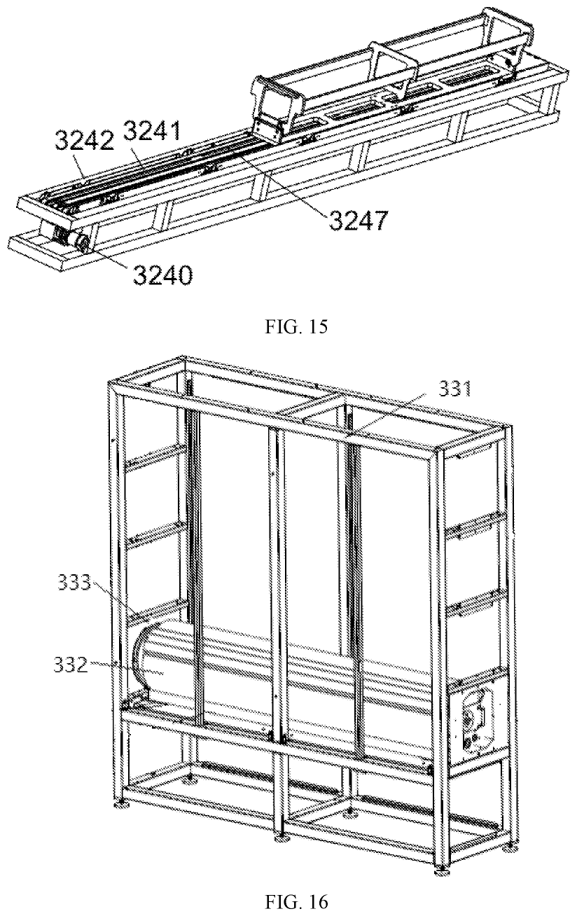

As shown in FIG. 1 to FIG. 22, an embodiment of the present application provides a production line 10 for producing a solar cell, which is applied to manufacture an N-type silicon wafer 1 into a solar cell. The production line 10 for producing the solar cell includes: a texturing device 2, a heat treatment system 3, a phosphorus diffusion device 7, an etching device 6, a passivation system 8 and an electrode manufacturing system 9.

The texturing device 2 is configured to perform a texturing process of the N-type silicon wafer 1. The heat treatment system 3 is configured to perform a boron diffusion process and a LPCVD process of the N-type silicon wafer 1. The phosphorus diffusion device 7 is configured to perform a phosphorus diffusion process on the N-type silicon wafer 1, to dope intrinsic amorphous silicon layer on a back side of the N-type silicon wafer with phosphorus, and perform a post-oxidation treatment, so that a phosphorus-rich layer is formed on the back side of the N-type silicon wafer 1. The etching device 6 is configured to perform an etching process of the N-type silicon wafer 1. The passivation system 8 is configured to perform a passivation layer process, a front film process and a back film process of the N-type silicon wafer 1. The electrode manufacturing system 9 is configured to perform a preparation process of electrodes on two sides of the N-type silicon wafer 1 to form the solar cell.

As shown in FIG. 4, the texturing device 2 includes a texturing loading apparatus 20, a texturing pre-cleaning tank 21, a texturing apparatus 22, a texturing post-cleaning tank 23, a texturing pickling tank 24, a texturing pre-dehydration tank 25, a texturing drying tank 26, and a texturing unloading apparatus 27 connected in sequence. The texturing loading apparatus 20 is configured to move the N-type silicon wafer 1 to the texturing pre-cleaning tank 21 for cleaning. The texturing pre-cleaning tank 21 is configured to remove an impurity on a surface of the N-type silicon wafer 1 to prepare for subsequent texturing. The texturing apparatus 22 is configured to form a texture structure on the surface of a pre-cleaned N-type silicon wafer 1 by using an alkaline solution. For example, the alkaline solution may be sodium hydroxide or potassium hydroxide. In general, the textured structure is formed in a shape of multiple triangles to increase the number of light refractions on the surface of the N-type silicon wafer 1, thereby increasing an optical path length of a light in the N-type silicon wafer 1, and improving utilization of sunlight. The texturing post-cleaning tank 23 is configured to clean the N-type silicon wafer 1 after the texture structure is formed on the surface of the N-type silicon wafer 1 to remove an impurity on the surface of the N-type silicon wafer 1. The texturing pickling tank 24 is configured to pickle the N-type silicon wafer with acid to neutralize the alkaline solution and remove a metal ion from the surface of the N-type silicon wafer 1. The texturing pre-dehydration tank 25 is configured to dehydrate the N-type silicon wafer 1 after the N-type silicon wafer 1 is pickled. The texturing drying tank 26 is configured to dry the N-type silicon wafer 1 after the N-type silicon wafer 1 is dehydrated. The texturing unloading apparatus 27 is configured to convey the N-type silicon wafer 1 completing the texturing process to the heat treatment system 3 for further processing.

After the N-type silicon wafer 1 is textured, the N-type silicon wafer 1 is cleaned by the texturing post-cleaning tank 23 and the texturing pickling tank 24. Cleaning agents used are RCA1 (a mixture of hydrogen peroxide, ammonia, and deionized water in a volume ratio of 1:1:5) and RCA2 (a mixture of hydrochloric acid, ammonia, and deionized water in a volume ratio of 1:1:6), to remove one or more combinations of the impurity, a surface damage layer, a cutting line mark, and a metal ion from the surface of the N-type silicon wafer 1, to prepare for a subsequent diffusion process. After the N-type silicon wafer 1 is cleaned and pickled, the N-type silicon wafer 1 is maintained clean by the texturing pre-dehydration tank 25 and the texturing drying tank 26. The texturing unloading apparatus 27 transports the N-type silicon wafer 1 that has completed the texturing process to the heat treatment system 3 for processing. It may be understood that each apparatus in the above texturing device 2 may be configured based on a specific need of the texturing process, such as increasing or reducing corresponding apparatus, or integrating one or more apparatuses.

As shown in FIG. 5 to FIG. 16, the heat treatment system 3 includes a loading and unloading system 31, a carrier conveying and purifying system 32, and a furnace tube system 33. The texturing unloading apparatus 27 of the texturing device 2 is connected to the loading and unloading system 31 of the heat treatment system 3. Optionally, the heat treatment system 3 may include a low-pressure level heat treatment system.

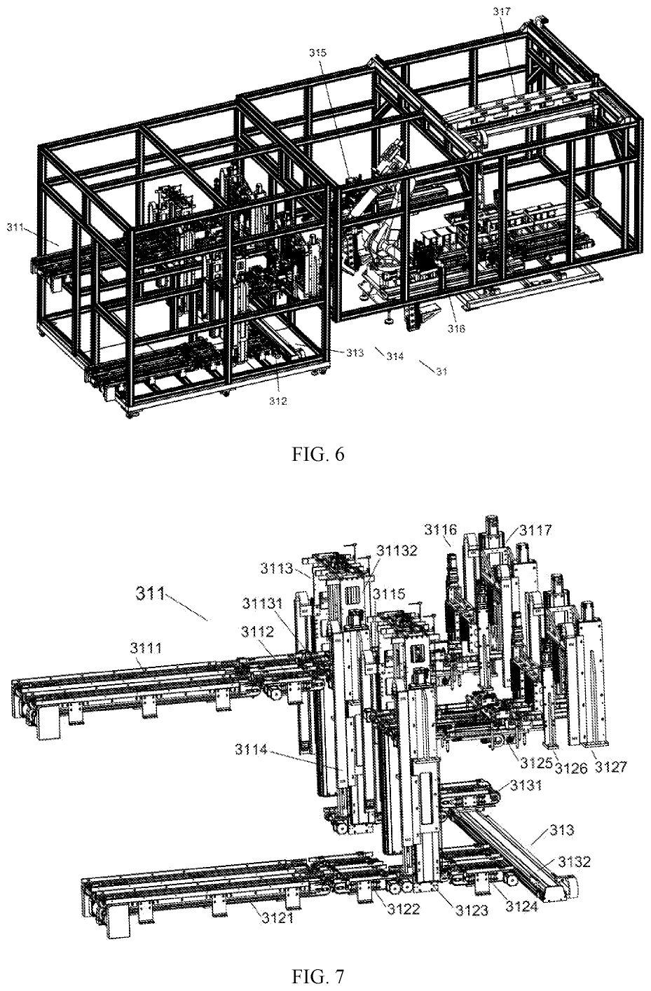

Referring to FIG. 6, the loading and unloading system 31 includes a loading wafer-guiding assembly 311, a unloading wafer-guiding assembly 312, a wafer-guiding circulation conveying mechanism 313, a silicon wafer grabbing apparatus 314, a loading carrying mechanism 315, a unloading carrying mechanism 316, and a carrier circulation mechanism 317. The carrier conveying and purifying system 32 includes a carrier carrying system 321, a carrier pushing system 322, a purifying and cooling system 323, a transmission system 324, and a purification table frame 325. The furnace tube system 33 includes a furnace tube rack 331 and a process furnace tube 332. The transmission system 324 is connected to both the carrier circulation mechanism 317 and the carrier carrying system 321, and is configured to perform a circulation of a carrier between the loading and unloading system 31 and the carrier conveying and purifying system 32. The carrier pushing system 322 is connected to the process furnace tube 332, and is configured to perform a circulation of the carrier between the carrier conveying and purifying system 32 and the furnace tube system 33. The process furnace tube 332 include a LPCVD furnace tube, a boron diffusion furnace tube, and an annealing furnace tube. The LPCVD furnace tube is configured to perform the LPCVD process, the boron diffusion furnace tube is configured to perform the boron diffusion process, and the annealing furnace tube is configured to perform an annealing process.

A carrier 319 is configured to circulate between the loading and unloading system 31, the carrier conveying and purifying system 32, and the furnace tube system 33. The N-type silicon wafer 1 is horizontally placed inside the carrier 319. The carrier 319 includes a carrier limiting plate 3194, and the N-type silicon wafers 1 is horizontally placed in the carrier limiting plate 3194 back to back. The carrier limiting plate 3194 is configured to shield three sides of the N-type silicon wafer 1 to prevent the N-type silicon wafer 1 from being wrap-around plated.

The loading and unloading system 31 includes a wafer guiding apparatus. The wafer guiding apparatus includes: the loading wafer-guiding assembly 311, the unloading wafer-guiding assembly 312, the wafer-guiding circulation conveying mechanism 313, the loading carrying mechanism 315, the unloading carrying mechanism 316 and the carrier circulation mechanism 317. The silicon wafer grabbing apparatus 314 is configured to perform operations such as suction, turn-over, movement . . . of silicon wafer. The silicon wafer grabbing apparatus 314 includes a six-axis robot 3131 and a silicon wafer grabbing and releasing mechanism 3142. The silicon wafer grabbing and releasing mechanism 3142 is configured to control suction to the N-type silicon wafer 1 and turn-over of the N-type silicon wafer 1. The six-axis robot 3131 is configured to control movement of the N-type silicon wafer 1 through the silicon wafer grabbing and releasing mechanism 3142. The loading and unloading system 31 includes a silicon wafer loading system and a silicon wafer unloading system. The silicon wafer loading system includes the loading wafer-guiding assembly 311, the silicon wafer grabbing apparatus 314, the loading carrying mechanism 315 and the carrier circulation mechanism 317. The silicon wafer unloading system includes: the unloading wafer-guiding assembly 312, the silicon wafer grabbing apparatus 314, the unloading carrying mechanism 316 and the carrier circulation mechanism 317.

The loading wafer-guiding assembly 311 includes a first loading connection conveying mechanism 3111, a first temporary storage conveying mechanism 3112, a first cassette lifting mechanism 3113, a first cassette conveying mechanism 3114, a first silicon wafer conveying mechanism 3115, a first silicon wafer temporary storage mechanism 3116, and a first wafer receiving mechanism 3117. The first cassette conveying mechanism 3114 is located below the first cassette lifting mechanism 3113. The unloading wafer-guiding assembly 312 includes a second loading connection conveying mechanism 3121, a second temporary storage conveying mechanism 3122, a second cassette lifting mechanism 3123, a second cassette conveying mechanism 3124, a second silicon wafer conveying mechanism 3125, a second silicon wafer temporary storage mechanism 3126 and a second wafer receiving mechanism 3127, and the second cassette conveying mechanism 3124 is located below the second cassette lifting mechanism 3123. The wafer-guiding circulation conveying mechanism 313 is both connected to the first cassette conveying mechanism 3114 and the second cassette conveying mechanism 3124. A cassette flows between the loading wafer-guiding assembly 311 and the unloading wafer-guiding assembly 312 through the first cassette conveying mechanism 3114, the wafer-guiding circulation conveying mechanism 313 and the second cassette conveying mechanism 3124.

In the embodiment, the loading wafer-guiding assembly 311 and the unloading wafer-guiding assembly 312 are the same in structure. Two sets of the loading wafer-guiding assembly 311 and the unloading wafer-guiding assembly 312 are symmetrically distributed. The following loading wafer-guiding assembly 311 is as an example for explanation. The first loading connection conveying mechanism 3111 adopts an automated guided vehicle (AGV) conveying line, and the first loading connection conveying mechanism 3111 has a length capable of accommodating a plurality of groups of cassettes for simultaneous conveying. Both ends of the first loading connection conveying mechanism 3111 in a conveying direction are fixedly provided with loading blocking cylinders (not shown in the figures). Two sets of loading through-beam sensors (not shown in the figures) are symmetrically and fixedly arranged on two sides, close to the first temporary storage conveying mechanism 3112, of end face of the first loading connection conveying mechanism 3111. The two sets of loading through-beam sensors and the loading blocking cylinders work together to achieve a purpose that the cassettes are sequentially and individually conveyed to the first temporary storage conveying mechanism 3112. In addition, the first loading connection conveying mechanism 3111 is further provided with a plurality of sensors (not shown in the figures), the number of the sensors is consistent with the number of the cassettes that the first loading connection conveying mechanism 3111 may carry at a time, and a distance between adjacent sensors is adjustable. The sensor detects a full or short material status of the cassette, thereby achieving fine control of the number of silicon wafers.

The first cassette lifting mechanism 3113 includes a lifting conveying assembly 31131 and a cassette lifting assembly 31132. The cassette lifting assembly 31132 controls the lifting conveying assembly 31131 to ascend and descend, and a length of the lifting conveying assembly 31131 is matched with a length of a single cassette. The first temporary storage conveying mechanism 3112 conveys a single cassette to the lifting conveying assembly 31131, and the cassette located on the lifting conveying assembly 31131 is fixed by a clamping apparatus, thereby preventing the first silicon wafer conveying mechanism 3115 from deviating when the wafer is taken that affects wafer taking efficiency. In the embodiment, the cassette lifting assembly 31132 adopts a ball screw transmission method to control the lifting conveying assembly 31131 to ascend and descend. The first cassette lifting mechanism 3113 further includes a through-beam sensor configured to detect remaining amount of silicon wafers in the cassette and an orientation sensor (not shown in the figures) configured to detect a orientation of a loading cassette to prevent a reverse placement error when the cassette is conveyed.

The first silicon wafer conveying mechanism 3115 is configured to take the N-type silicon wafer located in the cassette on the first cassette lifting mechanism 3113, and sequentially take the wafer through a lifting function of the lifting conveying assembly 31131 of the first cassette lifting mechanism 3113. The first silicon wafer conveying mechanism 3115 is extended and connected to a first end of the first silicon wafer temporary storage mechanism 3116, and a second end of the first silicon wafer temporary storage mechanism 3116 is extended and connected to the first wafer receiving mechanism 3117. After the N-type silicon wafer is conveyed to the first silicon wafer conveying mechanism 3115, the N-type silicon wafer flows into the first wafer receiving mechanism 3117 sequentially through the first silicon wafer conveying mechanism 3115 and the first silicon wafer temporary storage mechanism 3116. At the same time, the first silicon wafer conveying mechanism 3115 is configured to adjust the N-type silicon wafer, so that the N-type silicon wafer maintains uniformity during a transmission process, inflow of the N-type silicon wafer is facilitated, and inflow efficiency of N-type silicon wafers is improved.

The first wafer receiving mechanism 3117 is provided with a first wafer receiving groove (not shown in the figures). The first wafer receiving mechanism 3117 sequentially guides the silicon wafer conveyed by the first silicon wafer conveying mechanism 3115 and the first silicon wafer temporary storage mechanism 3116 into the first wafer receiving groove.

The first silicon wafer temporary storage mechanism 3116 is located between the first silicon wafer conveying mechanism 3115 and the first wafer receiving mechanism 3117. The first silicon wafer temporary storage mechanism 3116 is fixedly provided with a plurality of temporary storage grooves (not indicated in figures), a length direction of the temporary storage groove is consistent with a silicon wafer conveying direction of the first silicon wafer conveying mechanism 3115, and the adjacent temporary storage grooves are vertically arranged in parallel. The first silicon wafer temporary storage mechanism 3116 serves as a mechanism for temporarily storing the silicon wafer, to avoid a situation where the first wafer receiving groove of the first wafer receiving mechanism 3117 is filled with silicon wafers but the silicon wafer is not taken, a purpose of sequentially importing N-type silicon wafers conveyed on the first silicon wafer conveying mechanism 3115 into the temporary storage grooves is achieved.

The wafer-guiding circulation conveying mechanism 313 includes a circulation conveying assembly 3131 and a circulation moving assembly 3132. The circulation moving assembly 3132 includes a traversing drive assembly, and the traversing drive assembly adopts a ball screw drive method to drive the circulation conveying assembly 3131 to move relative to the circulation moving assembly 3132. In a moving process, the circulation conveying assembly 3131 is both connected to the first cassette conveying mechanism 3114 and the second cassette conveying mechanism 3124, and a upper end face of the circulation conveying assembly 3131 is located on the same horizontal plane as upper end faces of the first cassette conveying mechanism 3114 and the second cassette conveying mechanism 3124, so as to ensure smooth transition of the cassette.

The silicon wafer grabbing apparatus 314 includes a six-axis robot 3141 and a silicon wafer grabbing and releasing mechanism 3142. The six-axis robot 3141 controls space movement of the silicon wafer grabbing and releasing mechanism 3142, so that movement of the N-type silicon wafer and taking and placing operations are more flexible, beneficial to improving a speed of taking and placing the N-type silicon wafer and overall automation degree.

The silicon wafer grabbing and releasing mechanism 3142 includes a silicon wafer grabbing and separating mechanism 31421, a silicon wafer grabbing suction cup mechanism 31422, and a silicon wafer grabbing and rotating mechanism 31423. The silicon wafer grabbing suction cup mechanism 31422 includes a suction cup suctioning apparatus and an adjusting apparatus for controlling displacement of the suction cup suctioning apparatus. The silicon wafer grabbing and rotating mechanism 31423 includes a suction cup wafer suctioning apparatus and a rotating apparatus for controlling rotation of the suction cup wafer suctioning apparatus. The silicon wafer grabbing and separating mechanism 31421 controls movement of the silicon wafer through the silicon wafer grabbing suction cup mechanism 31422 and the silicon wafer grabbing and rotating mechanism 31423, the suction cup suctioning apparatus and the suction cup wafer suctioning apparatus control the suction and releasing of the silicon wafer, and the rotating apparatus controls the N-type silicon wafer to turn over.

The loading carrying mechanism 315 includes a first carrying positioning moving assembly 3151, a first carrying silicon wafer lifting assembly 3152, a first carrying silicon wafer regularing assembly 3153, and a first carrying ion blowing assembly (not shown in the figures). The unloading carrying mechanism 316 includes a second carrying positioning moving assembly 3160, a second carrying silicon wafer lifting assembly 3161, a second carrying silicon wafer regularing assembly 3162 and a second carrying ion blowing assembly (not shown in the figures). In the embodiment, the loading carrying mechanism 315 and the unloading carrying mechanism 316 are the same in structure. Taking the loading carrying mechanism 315 as an example, the first carrying positioning moving assembly 3151 may be horizontally placed the carrier that is configured to bear the N-type silicon wafer, and enables the first carrying silicon wafer lifting assembly 3152 to pass through interior of the carrier when the first carrying silicon wafer lifting assembly 3152 is in a rising state. The six-axis robot 3141 may drive the silicon wafer grabbing and releasing mechanism 3142 to move the silicon wafer from the first wafer receiving mechanism 3117 to a tooth groove of the first carrying silicon wafer lifting assembly 3152 in the rising state. After the silicon wafer enters the first carrying silicon wafer lifting assembly 3152, the first carrying silicon wafer regularing assembly 3153 may regular the silicon wafer from two sides of the silicon wafer. After the silicon wafer is regulared, the first carrying silicon wafer lifting assembly 3152 descends, so that the silicon wafer falls into the carrier. In a process that the silicon wafer enters the carrier, the first carrying ion blowing assembly may facilitate separation of the silicon wafers and the silicon wafer to fall into the tooth groove of the carrier by blowing air between adjacent silicon wafers.

The carrier circulation mechanism 317 includes a transmission connection conveying assembly 3171, a clamping jaw assembly 3172, and a movement module assembly 3173 for controlling movement of the clamping jaw assembly 3172. The transmission connection conveying assembly 3171 is configured to be capable of bearing a plurality of carriers, for example, the transmission connection conveying assembly 3171 includes a carrier holder for bearing the carrier. The movement module assembly 3173 controls the clamping jaw assembly 3172 with clamped carrier to flow between the carrier holder of the transmission connection conveying assembly 3171 and the loading carrying mechanism 315.

In order to avoid a problem of wrap-around plating, in the embodiment, a specially-designed carrier is used to support the silicon wafer, and the carrier supports the silicon wafer to enter the process furnace tube for processing. The carrier 319 includes a carrier top plate 3191, a carrier bottom plate 3192, a carrier support rod 3193 and a carrier limiting plate 3194. The carrier top plate 3191 and the carrier bottom plate 3192 are connected by the carrier support rod 3193, forming a placement space for placing the silicon wafer. The carrier 319 has a simple overall structure and is with a lighter weight, and a load range is expanded as much as possible. The carrier support rod 3193 is provided with carrier clamping plates 31931 at intervals along a length direction, and a clamping plate cavity 31932 is formed between two adjacent carrier clamping plates 31931. The carrier limiting plate 3194 is installed in the clamping plate cavity 3193.

A plurality of groups of carrier support rods 3193 are provided, and are distributed between the carrier top plate 3191 and the carrier bottom plate 3192. The number of the carrier support rods 3193, the shape of the carrier top plate 3191, and the shape of the carrier bottom plate 3192 are all adapted to the silicon wafer. For example, the silicon wafer is rectangular, the entire carrier is formed to be a cuboid, and four carrier support rods 3193 are distributed on four corners of the carrier top plate 3191 and the carrier bottom plate 3192. The carrier clamp plate 31931 is fixedly arranged on opposite surfaces of the two opposite carrier supporting rods 3193 on the left and right sides, and corresponding clamp cavity 31932 on each carrier support rod 3193 is in the same horizontal plane. The carrier limiting plate 3194 is installed in a plurality of sets of clamp cavities 31932 located in the same horizontal plane.

The carrier limiting plate 3194 includes two groups of carrier limiting side plates mounted in the clamping plate cavity 31932, and a carrier limiting connecting plate connected to the two groups of carrier limiting side plates. The carrier limiting side plate and the carrier limiting connecting plate are the same in structure. In an embodiment, the carrier limiting side plate and the carrier limiting connecting plate are integrally formed. In the embodiment, a cross-sectional shape of the clamping plate cavity 31932 in a vertical direction is rectangular, an upper side surface and a lower side surface of the carrier limiting side plate abut against a upper side face and a lower side face of the clamping plate cavity 31932, and a long clamping plate cavity 31932 may ensure installation stability of the carrier limiting side plate. Silicon wafer placing cavities 31941 are fixedly arranged on the carrier limiting side plate and the carrier limiting connecting plate, and corresponding silicon wafer placing cavities 31941 on the carrier limiting side plate and the carrier limiting connecting plate are located on the same horizontal plane. A cross-sectional shape of a silicon wafer placing cavitiy 31941 in the vertical direction is not limited. In the embodiment, a cross-sectional shape of the silicon wafer placing cavity 31941 is square, the N-type silicon wafer is supported by line contact or surface contact with the silicon wafer placing cavity 31941, and the silicon wafer placing cavity 31941 may accommodate two groups of silicon wafer to be stacking installed.

According to the embodiment, when the silicon wafer is placed in the carrier, three sides of the N-type silicon wafer are shielded by the carrier limiting plate 3194 except for one side of a placing direction of the N-type silicon wafer, so that gas may be effectively prevented from entering a back-to-back contacting surface from a back-to-back N-type silicon wafer gap, thereby effectively avoiding wrap-around plating, and achieving no wrap-around plating or micro-wrap-around plating. In this way, processing of the wrap-around plating layer may be removed, so that a continuous process in the same device system is realized without the need for offline unloading for wet processing.

The carrier top plate 3191 of the carrier is parallel to the carrier bottom plate 3192 of the carrier, providing maximum space for placing carrier plate as much as possible. Because when the carrier top plate 3191 and the carrier bottom plate 3192 of the carrier are not parallel, some space may not be used for horizontal placement of silicon wafers, wasting space and increasing the weight of the carrier.

The carrier is made of a non-conductive, high-temperature resistant, and pressure resistant material. For example, the material is selected as quartz or silicon carbide, in order to reduce the weight of the carrier as much as possible, increase the number of placed carrier plates in the entire carrier, and also conforms to the non-conductive and high-temperature resistance characteristics of the carrier.

In order to ensure stability of the overall structure of the carrier, a carrier connecting shaft 3195 is fixedly arranged between the carrier support rods 3193, and a carrier support plate 31951 is fixedly arranged on the carrier connecting shaft 3195. The carrier support plate 31951 is in the same horizontal plane as a center of gravity of the entire carrier, beneficial for increasing stability of taking and placing the carrier, and deviation of the carrier during transportation is not easy to be caused. A shape of the carrier support plate 31951 may be set based on an actual need, generally rectangle is used, but other shapes may alternatively be used, as long as it is convenient for a mechanical arm to take and place, and support of the carrier holder.

In an implementation process of the loading and unloading system 31, the cassettes filled with silicon wafers are sequentially conveyed to the first temporary storage conveying mechanism 3112 by the first loading connection conveying mechanism 3111 in a form of individual cassette, and the first temporary storage conveying mechanism 3112 conveys the cassette to the first cassette lifting mechanism 3113. The silicon wafers in the cassette are sequentially conveyed out through the first silicon wafer conveying mechanism 3115, and the silicon wafers located on a conveying line are sequentially fed into the first wafer receiving groove of the first wafer receiving mechanism 3117 through the coordinated operation of the first silicon wafer conveying mechanism 3115 and the first wafer receiving mechanism 3117. The suction cup suctioning apparatus of the silicon wafer grabbing and releasing mechanism 3142 suctions the silicon wafer from the first receiving groove, the six-axis robot 3141 moves the silicon wafer to the loading carrying mechanism 315, and performs back-to-back lamination of the silicon wafer. Above steps are repeated until the carrier on the loading carrying mechanism 315 is filled. The carrier filled with silicon wafers is carried to the carrier holder of the transmission connection conveying assembly 3171 through the clamping jaw assembly 3172 controlled by the transmission connection conveying assembly 3171, until the carrier holder is filled with the carriers. The transmission connection conveying assembly 3171 is connected to the carrier conveying and purifying system 32. The transmission connection conveying assembly 3171 moves the carrier holder to the carrier conveying and purifying system 32, realizing a movement process of the silicon wafers from the wafer guiding apparatus to the carrier conveying and purifying system 32. The carrier conveying and purifying system 32 transfers silicon wafer that has undergone boron diffusion process from the carrier conveying and purifying system 32 to the transmission connection conveying assembly 3171. The carrier filled with N-type silicon wafers that have undergone boron diffusion process is transported to the unloading carrying mechanism 316 through the clamping jaw assembly 3172. Reverse circulation is carried out based on the above structure, thereby realizing a movement process of silicon wafers from the carrier conveying and purifying system 32 to the wafer guiding apparatus.

The carrier conveying and purifying system 32 includes a carrier carrying system 321, a carrier pushing system 322, a purifying and cooling system 323, a transmission system 324, and a purification table frame 325. The purifying and cooling system 323 is located outside the purification table frame 325, and is configured to purify gas of the carrier conveying and purifying system 32. The transmission system 324 is configured to transfer a carrier loaded with an unprocessed N-type silicon wafer located in the loading and unloading system 31 to the carrier carrying system 321, and transfer a carrier loaded with a processed N-type silicon wafer to the loading and unloading system 31, so as to perform a carrier interaction between the carrier carrying system 321 and the loading and unloading system 31. The carrier carrying system 321 is configured to move the carrier loaded with the unprocessed N-type silicon wafer to the carrier pushing system 322. The carrier pushing system 322 is configured to move the carrier loaded with the unprocessed N-type silicon wafer to the furnace tube system 33 for processing. The carrier pushing system 322 is further configured to move out the carrier loaded with the processed N-type silicon wafer and move the carrier loaded with the processed N-type silicon wafer to the transmission system 324 through the carrier carrying system 321.

That is to say, the transmission system 324 is configured to perform the carrier interaction between the carrier carrying system 321 and the loading and unloading system 31. Specifically, on the one hand, the carrier carrying system 321 moves the carrier loaded with unprocessed N-type silicon wafers to the carrier pushing system 322, and the pushing carrier system 322 moves the carrier loaded with unprocessed N-type silicon wafers to the furnace tube system 33 for boron diffusion process; on the other hand, the carrier pushing system 322 moves the carrier loaded with the processed N-type silicon wafer out and moves the carrier loaded with the processed N-type silicon wafer to the transmission system 324 through the carrier carrying system 321.

The carrier carrying system 321 includes a carrier carrying column 3211, a carrier carrying head 3212, and a Z-axis transmission structure 3214. The carrier carrying head 3212 is movably arranged on the carrier carrying column 3211 through the Z-axis transmission structure 3214. The carrier carrying head 3212 includes a first-stage arm 32121, a second-stage arm 32122, a first X-axis transmission structure 32123, a second X-axis transmission structure 32124, and a carrier carrying mechanical gripper 3213. The first-stage arm 32121 and the second-stage arm 32122 are movably connected through the first X-axis transmission structure 32123. The carrier carrying mechanical gripper 3213 is movable arranged on the second-stage arm 32122 through the second X-axis transmission structure 32124. The first X-axis transmission structure 32123 includes a first X-axis servo motor 32125, and the first X-axis servo motor 32125 is located on outer side of the first-stage arm 32121. The carrier carrying mechanical gripper 3213 is configured to support and lift the carrier holder.

The carrier carrying system 321 further includes a temporary storage carrier carrying mechanical hand 3215 fixed on the carrier carrying column 3211. The temporary storage carrier carrying mechanical hand 3215 is correspondingly arranged on two carrier carrying columns 3211, and the temporary storage carrier carrying mechanical hand 3215 is configured to temporarily store a carrier holder. In the example, six temporary storage carrier carrying mechanical hands 3215 may be arranged on one carrier carrying column 3211. Therefore, maximum number of carrier holders that may be temporarily stored simultaneously on two carrier carrying columns 3211 is six. The carrier moving system 321 further includes a photoelectric limit sensor 3216. The photoelectric limit sensor 3216 is arranged on the carrier carrying column 3211, and may be configured to sense positions of the carrier carrying head 3212, the first-stage arm 32121, the second-stage arm 32122, and the carrier carrying mechanical gripper 3213, and accuracy of position control of the apparatus is improved.

The carrier carrying system 321 controls movement of the carrier carrying head 3212 in a Z-axis direction by arranging the Z-axis transmission structure 3214 on the carrier carrying column 3211. Movement of the second-stage arm 32122 and the carrier carrying mechanical gripper 3213 in an X-axis direction is controlled by arranging the first X-axis transmission structure 32123 and the second X-axis transmission structure 32124 of the carrier carrying head 3212.

During an implementation of the carrier carrying system 321, the transmission system 324 acquires the carrier holder from the loading and unloading system 31 and transmits the carrier holder, and the carrier carrying mechanical gripper 3213 moves the carrier holder from the transmission system 324 to the carrier pushing system 322. In a continuous production, the temporary storage carrier carrying mechanical hand 3215 temporarily stores the carrier holder.

The carrier pushing system 322 includes a carrier pushing conveying mechanism 3221, a carrier pushing paddle 3222, and a carrier pushing furnace door 3223. The carrier pushing paddle 3222 is connected to the carrier pushing furnace door 3223, and moves synchronously with the carrier pushing furnace door 3223. The carrier pushing paddle 3222 is configured to support and bear the carrier holder and the carrier 319. The carrier 319 is loaded with the silicon wafer, and the carrier pushing conveying mechanism 3221 drives the carrier pushing paddle 3222 to move back and forth to control the carrier support and carrier 319 to enter and exit the process furnace tube 332.

A sliding direction of the carrier pushing conveying mechanism 3221 is consistent with a axial direction of the process furnace tube 332.

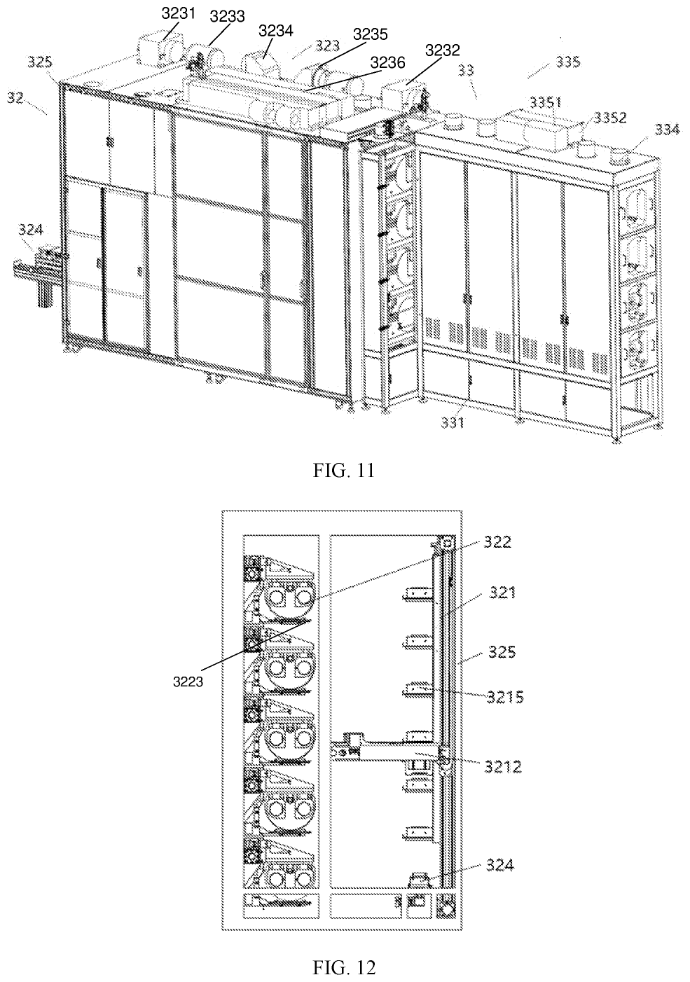

The purifying and cooling system 323 includes a purifying apparatus and a cooling apparatus. The purifying apparatus includes a first filter 3231, a second filter 3232, a purification fan 3233, a first air inlet 3234, and a second air inlet 3235 (as shown in FIG. 11). The first filter 3231, purification fan 3233, first air inlet 3234, second air inlet 3235 and second filter 3232 are horizontally arranged above the purification table frame 325, and are connected through a pipeline. According to the embodiment, the first filter 3231 and the second filter 3232 uses an air filter element for purifying, adopting a physical purification method. The number of the first filter 3231 and the second filter 3232 are at least one group. According to the embodiment, the number of the first filter 3231 and the second filter 3232 are two groups, and the first filter 3231 and the second filter 3232 are both connected to internal space of the purification table frame 325 through a gas pipeline structure (not shown in the figures). The first filter 3231 and the second filter 3232 introduce air outside the purification table frame 325 that has been purified by the purification fan 3233 into interior of the purification table frame 325. Since the silicon wafer process requires a clean environment, the gas entering the frame of the carrier conveying and purifying 32 needs to be filtered and purified first. In the embodiment, a purpose of arranging the first filter 3231 and the second filter 3232 as two groups is to ensure uniform airflow inside the purification table frame 325, avoid occurrence of large airflow on one side and small airflow on the other side, and ensure uniform heat dissipation of the silicon wafer. By arranging the first filter 3231 and the second filter 3232 to introduce purified cold air, internal cooling of the purification table frame 325 may be greatly achieved without introducing pollution.

The purification fan 3233 as well as the first air inlet 3234 and the second air inlet 3235 are designed to ensure air circulation inside the purification table frame 325. The purification fan 3233 is connected to the first air inlet 3234 and the second air inlet 3235 separately. The first air inlet 3234 and the second air inlet 3235 are respectively equipped with an airflow guiding outlet (not shown in the figures). The guiding outlet is disposed on side of the first air inlet 3234 and the second air inlet 3235, in order to prevent dust from falling into the interior of the purification table frame 325 along the first air inlet 3234 and the second air inlet 3235 when the first air inlet 3234 and the second air inlet 3235 are not in operation. The gas outside the purification table frame 325 may be drawn into the interior of the purification table frame 325 through the first air inlet 3234 and the second air inlet 3235. The first air inlet 3234 and the second air inlet 3235 with the first filter 3231 and the second filter 3232 achieves airflow flow inside and outside the purification table frame 325.

The cooling apparatus includes the first air inlet 3234, the second air inlet 3235, the air outlet, and the purification fan 3233, and the air outlet is located inside the carrier conveying and purifying system 32. In order to improve cooling efficiency inside the purification table frame 325, the first air inlet 3234, the second air inlet 3235, the air outlet, and the purification fan 3233 are used to form an air cooling method. The embodiment may alternatively adopt a combination of an air cooling apparatus and a water cooling apparatus. The water cooling apparatus includes a water cooling disc 3236 and a water cooling pipeline (not shown in the figures). The water cooling disc 3236 and the water cooling pipeline form a closed circulating circuit. One side of the water cooling disc is equipped with a water cooling disc fan, and the water cooling disc fan provided on the water cooling disc is configured to achieve rapid cooling of the water cooling disc. Hot air inside the carrier conveying and purifying system 32 may be pumped up and cooled by the water cooling disc, and then the cooled hot air is discharged outside the carrier conveying and purifying system 32 or inside the carrier conveying and purifying system 32 for internal circulation. When the hot air flow inside the carrier conveying and purifying system 32 passes through the water cooling disc, the hot air flow exchanges heat with a heat dissipation fin set on the water cooling disc coil, so that temperature of the hot air flow decreases. The cooled hot airflow may be directly discharged to the outside or to the inside. The heat dissipation fin is made of aluminum or copper material. In the embodiment, the water cooling disc 3236 is further provided with a water inlet and outlet pipe. The water inlet and outlet pipe is vertically disposed at the top of the purification table frame 325, and is connected to the water cooling disc 3236 through a valve and a pipeline. The water cooling pipeline may be disposed above, on one side, or inside the purification table frame 325, or any combination thereof. In the embodiment, the water cooling pipeline is disposed above, on sides, and inside the purification table frame 325, and rapid cooling of the interior of the purification table frame 325 is achieved through water cooling combined with air cooling. In order to improve water cooling efficiency, specific coolant may alternatively be used to replace the water medium.

The transmission system 324 includes a transmission mechanism 3241 and a transmission frame 3242. The transmission mechanism 3241 is located on the transmission frame 3242 and is supported by the transmission frame 3242. The transmission mechanism 3241 includes a transmission drive assembly 3240, a transmission belt 3247, and a transmission tension assembly. The transmission mechanism 3241 transmits a carrier support plate assembly by means of the transmission belt 3247. The transmission tension assembly controls tension of the transmission belt 3247. The carrier support plate assembly is configured to bear the carrier holder. The carrier holder is configured to bear the carrier.

During a transmission process of the transmission system 324, the transmission drive assembly 3240 of the transmission mechanism 3241 controls transmission of the transmission belt 3247. The transmission of the transmission belt 3247 drives the carrier holder located on the carrier support plate assembly to move, thereby transferring a carrier loaded with a processed silicon wafer to the loading and unloading system 31, transferring a carrier the loaded with an unprocessed silicon wafer located on the loading and unloading system 31 to the carrier carrying system 321, and ensuring that the transmission mechanism 3241 achieves stable and reliable transmission of the carrier.

The furnace tube system 33 includes a furnace tube rack 331 and a process furnace tube 332. The process furnace tube 332 is horizontally mounted on the furnace tube rack 331, and an opening of the process furnace tube 332 faces the carrier pushing system 322. The carrier pushing system 322 moves the carrier 319 to the process furnace tube 332 through the carrier pushing conveying mechanism 3221 and the carrier pushing paddle 3222, or conveys the carrier 319 loaded with the processed silicon wafer out of the process furnace tube 332. When the carrier pushing paddle 3222 pushes the carrier 319 as far as possible into the process furnace tube 332, the carrier pushing furnace door 3223 may seal the opening of the process furnace tube 332, so that a cavity isolated from the outside is formed inside the process furnace tube 332. A tail of the process furnace tube 332 is provided with a gas conveying apparatus 333 that is connected to the interior of the process furnace tube. The gas conveying apparatus 333 regulates internal pressure of the process furnace tube 332. Generally, before introducing a reaction gas, the furnace needs to be evacuated to form a vacuum furnace state. Then, based on an actual reaction need, a gas is introduced for reaction, catalysis, or protection.

According to the embodiment, the heat treatment system 3 is configured to perform a boron diffusion process and a LPCVD process on the N-type silicon wafer 1.

The furnace tube system 33 includes process furnace tubes 332. Each type of process furnace tube 332 corresponds to the carrier carrying system 321. The process furnace tubes 332 are arranged in parallel, either vertically or horizontally, or both vertically and horizontally to form a combination of rows and columns to increase production. Each process furnace tube 332 can work independently with the carrier carrying system 321 to achieve continuous production. The process furnace tube 332 may include a LPCVD process furnace tube and a boron diffusion process furnace tube. The LPCVD process furnace tube is configured to perform a LPCVD process of the N-type silicon wafer, and the boron diffusion process furnace tube is configured to perform a boron diffusion process of the N-type silicon wafer, so that process apparatus and labor is saved, and transshipment damage of the silicon wafer is reduced. The furnace tube system 33 is designed with multiple sets of tubes arranged side by side, so that synchronous and orderly operation of loading and unloading of the loading and unloading system 31 and the silicon wafer process may be achieved. During a reacting process of one furnace, unloading of a previous furnace and loading of a subsequent furnace may be carried out, so that continuous high-yield production is achieved. In the embodiment, the furnace tube system 33 further includes an external vacuum pump 34, used to perform the LPCVD process; and a gas source cabinet 35, used to perform the boron diffusion process.

In some embodiments, the heat treatment system 3 may further be configured to perform an annealing process of the N-type silicon wafer 1. Optionally, the process furnace tubes 332 may include, in addition to the LPCVD process furnace tube and the boron diffusion process furnace tube, an annealing process furnace tube. The annealing process furnace tube is configured to perform an annealing process of the N-type silicon wafer. In this way, process apparatus and labor may be further saved, and transshipment damage of silicon wafer may be reduced.

In some embodiments, the LPCVD process tube, the boron diffusion process tube and the annealing process tube may alternatively be combined with other components to form from other apparatus, respectively. As an example, the LPCVD process tube may be combined with other components to form an independent LPCVD apparatus. The boron diffusion process furnace tube may be combined with other components to form an independent boron diffusion apparatus. The annealing process tube may be combined with other components to form an independent annealing process apparatus.

The gas conveying apparatus 333 includes a reaction gas conveying apparatus and a tail gas treatment apparatus. The reaction gas conveying apparatus introduces process gas to the process furnace tube 332. The tail gas treatment apparatus is configured to assist in unloading gas or balancing gas pressure.

The furnace tube system 33 further includes a furnace cavity air cooling apparatus 335 and a furnace tube rack cooling apparatus 334. The furnace cavity air cooling apparatus 335 includes a furnace tube rack air cooling disk 3351. The furnace tube rack air cooling disk 3351 is arranged on the top of the furnace tube rack 331. Multiple groups of air cooling exhaust vents 3352 are also arranged at the top of the furnace tube rack 331. Each group of air cooling exhaust vents 3352 corresponds to an exhaust fan. The exhaust fan is driven by the purification fan. An upward ventilation pipe is disposed on the furnace tube rack 331 where each group of process furnace tubes 332 is located. The ventilation pipe is connected to the furnace tube rack air cooling disk 3351 from the side of each group of process furnace tubes 332. The furnace cavity air cooling apparatus 335 discharges heat of the furnace tube rack 331, and the furnace tube rack cooling apparatus 334 reduces heat of discharged air, significantly reducing thermal radiation effect of high temperature of the process furnace tubes on the furnace tube environment during apparatus operation, so that the process temperature is prevented from being too high and affecting a normal operation of an electrical apparatus, and a production process cycle of the silicon wafer is greatly shortened, thereby improving production efficiency. Moreover, a combination of air cooling and water cooling methods is adopted, a pipeline structure is connected to the interior of the process furnace tube, a problem of impact of the heating of the process furnace tube on the silicon wafer production process is solved, so that a process cooling speed is accelerated, a process yield is improved, and a failure rate of electrical apparatus is reduced.

After the front side of the N-type silicon wafer 1 is textured, the textured N-type silicon wafer 1 is transported to the heat treatment system 3 by the texturing unloading apparatus 27 for boron diffusion process. The boron doped region 112 is formed on the textured surface of the N-type silicon wafer 1 through the boron diffusion process.

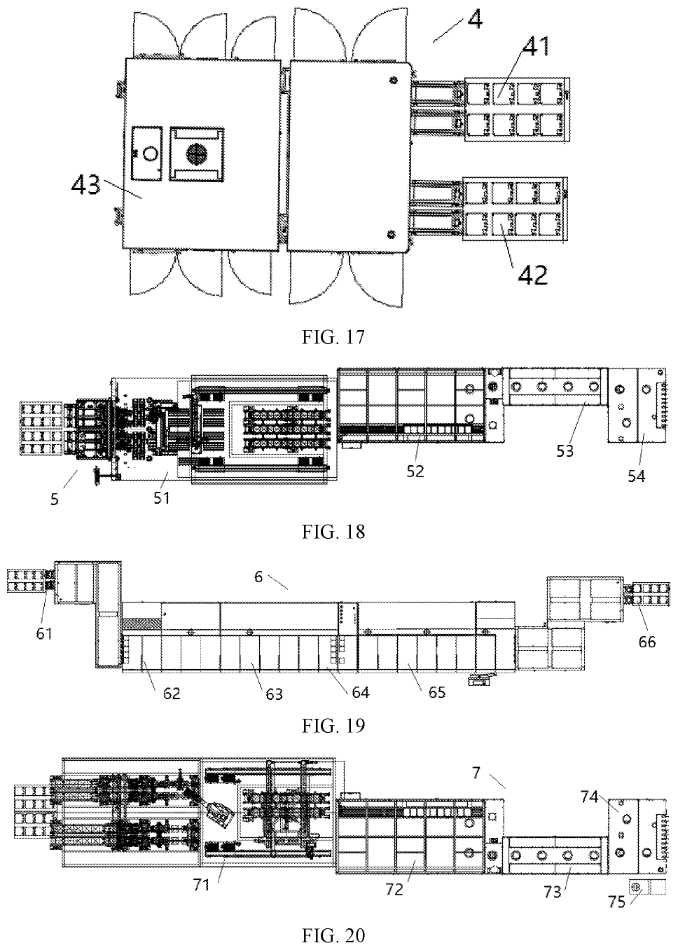

The production line 10 for producing the solar cell further includes a laser doping device 4. The laser doping device 4 is configured to perform laser local boron doping on a front side of the N-type silicon wafer 1 to form a boron heavily doped region, and perform laser local phosphorus doping on the back side of the N-type silicon wafer 1 to form a phosphorus heavily doped region. As shown in FIG. 17, the N-type silicon wafer 1 after boron diffusion is transported to the laser doping device 4. The laser doping device 4 includes a laser doping loading end 41, a laser processing cavity 43, and a laser unloading end 42. The loading and unloading system 31 of the heat treatment system 3 is connected to the laser doping loading end 41 of the laser doping device 4. A laser process apparatus is provided in the laser processing cavity 43. The laser process apparatus is configured to perform laser grooving on a textured surface, perform front laser local doping on a grooving region of an N-type silicon wafer 1 after boron diffusion to form the boron heavily doped region 113. The laser process apparatus includes a boron source. The boron source provides boron for the boron heavily doped region 113. The N-type silicon wafer 1 after laser local boron doping is transported from the laser processing cavity 43 to the laser unloading end 42.

The laser doping device 4 is further configured to perform laser grooving on a surface without being textured, perform front laser local doping on a grooving region of an N-type silicon wafer 1 after phosphorus diffusion to form the phosphorus heavily doped region 123. The laser process apparatus includes a phosphorus source. The N-type silicon wafer 1 after laser local phosphorus doping is transported from the laser processing cavity 43 to the laser unloading end 42.

The production line 10 for producing the solar cell further includes an oxidation system 5. The oxidation system 5 is configured to perform an oxidation process of the N-type silicon wafer 1 to protect the boron heavily doped region and the phosphorus heavily doped region. As shown in FIG. 18, the oxidation system 5 includes an oxidation loading and unloading apparatus 51, an oxidation purification table 52, an oxidation furnace body 53 and an oxidation gas cabinet 54. The laser unloading end 42 of the laser doping device 4 is connected to the oxidation loading and unloading apparatus 51 of the oxidation system 5. The N-type silicon wafer 1 after laser local boron doping is conveyed to the oxidation system 5, and the oxidation system 5 processes the N-type silicon wafer 1 to protect the boron heavily doped region 113. The N-type silicon wafer 1 after laser local phosphorus doping is conveyed to the oxidation system 5, and the oxidation system 5 processes the N-type silicon wafer 1 to protect the phosphorus heavily doped region 123.

Specifically, the oxidation loading and unloading apparatus 51 is configured to transfer a non-oxidized deposited N-type silicon wafer 1 to the oxidation furnace body 53 for an oxidation deposition process or to transfer an oxidized deposited N-type silicon wafer 1 to a next process. The oxidation purification table 52 has a structure similar to the structure of the carrier conveying and purifying system 32 and serves a similar function. The oxidation furnace body 53 has a structure similar to the structure of the furnace tube system 33, and is configured to perform the oxidation deposition process of the N-type silicon wafer 1. The oxidation gas cabinet 54 provides source gas or liquid for the oxidation deposition process of the oxidation furnace body 53. Optionally, the oxidation system 5 may include a low pressure horizontal oxidation system. Optionally, an N-type silicon wafer 1 after laser local boron doping may be obtained by performing laser local boron doping on an N-type silicon wafer 1 by using the laser doping device. Optionally, an N-type silicon wafer 1 after laser local phosphorus doping may be obtained by performing laser local phosphorus doping on an N-type silicon wafer 1 by using the laser doping device.

The etching device 6 is further configured to perform an alkali polishing process of the N-type silicon wafer 1. As shown in FIG. 19, the etching device 6 includes an alkali polishing and etching loading apparatus 61, an alkali polishing and etching protection apparatus 62, an alkali polishing and etching performing apparatus 63, an alkali polishing and etching alkali washing apparatus 64, an alkali polishing and etching pickling apparatus 65 and an alkali polishing and etching unloading apparatus 66. The alkali polishing and etching loading apparatus 61 of the etching device 6 is connected to the oxidation loading and unloading apparatus 51 of the oxidation system 5. An N-type silicon wafer 1 that has undergone the oxide deposition process is conveyed to the etching device 6 for cleaning and etching, to remove a boro silicate glass (BSG) layer on a front surface of the N-type silicon wafer 1, chemically polish a back surface of the N-type silicon wafer 1, and solve a problem that laser ablation is easy to form a dead layer or a damaged layer.

In the embodiment, the alkali polishing and etching loading apparatus 61 is connected to the oxidation system 5, the alkali polishing and etching unloading apparatus 66 is connected to the loading and unloading system 31 of the heat treatment system 3, an alkali polished and etched N-type silicon wafers 1 is transmitted to the heat treatment system 3 for a LPCVD process. During the LPCVD process, a tunneling silicon oxide passive film is generated on the N-type silicon wafers 1, and intrinsic polysilicon is deposited on the tunneling oxide layer. Optionally, the alkali polishing and etching unloading apparatus 66 may be connected to other apparatus capable of performing the LPCVD process to perform the LPCVD process. Other apparatus capable of performing the LPCVD process may include the LPCVD apparatus having the LPCVD furnace tube described above.

As shown in FIG. 20, the phosphorus diffusion device 7 includes a phosphorus diffusion loading and unloading system 71, a phosphorus diffusion purification table 72, a phosphorus diffusion furnace cabinet 73, a phosphorus diffusion gas cabinet 74 and a phosphorus diffusion phosphorus source cabinet 75. The loading and unloading system 31 of the heat treatment system 3 is connected to the phosphorus diffusion loading and unloading system 71 of the phosphorus diffusion device 7. A LPCVD processed N-type silicon wafer 1 is conveyed to the phosphorus diffusion device 7 for phosphorus diffusion. In the embodiment, the phosphorus diffusion device 7 uses a stepped phosphorus diffusion method to perform multiple phosphorus diffusion operations on a back side of the N-type silicon wafer 1, so that multiple layers of phosphorus doped region 122 is formed on the back side of the N-type silicon wafer 1. After phosphorus diffusion, a post-oxidation treatment is performed, so that a phosphorus-rich layer is formed on the back side of the N-type silicon wafer 1. And thourgh the process, concentration of phospho silicate glass (PSG) on a outer surface of N-type silicon wafer is increased, and a PSG layer is formed.

In some implementations, the phosphorus diffusion device 7 may includes a plasma enhanced chemical vapor deposition (PECVD) apparatus. The PECVD apparatus is configured to perform a PECVD process of N-type silicon wafer 1 to form the aforementioned phosphorus-rich layer on the back side of N-type silicon wafer 1.

In some embodiments, the heat treatment system 3 may further be configured to perform the phosphorus diffusion process of the N-type silicon wafer 1. Specifically, the process furnace tubes 332 may include a PECVD furnace tube. In these embodiments, the above-mentioned phosphorus diffusion device 7 may be omitted, and the above-mentioned phosphorus layer may be formed on the back side of the N-type silicon wafer 1 through the heat treatment system 3.

Optionally, besides performing the boron diffusion processes, the heat treatment system 3 may be configured to perform one or a combination of following processes of the N-type silicon wafer 1: an annealing process, a LPCVD process, and a phosphorus diffusion process. For example, the heat treatment system 3 is configured to perform the boron diffusion process of the N-type silicon wafer 1, and the LPCVD process and phosphorus diffusion process may be performed respectively by other device other than the heat treatment system 3. For example, the heat treatment system 3 may be configured to perform the boron diffusion process, LPCVD process, and phosphorus diffusion process of the N-type silicon wafer 1. For another example, the heat treatment system 3 may be configured to perform the boron diffusion process and LPCVD process of the N-type silicon wafer 1, and the phosphorus diffusion device 7 may be configured to perform the phosphorus diffusion process of the N-type silicon wafer 1. For another example, the heat treatment system 3 may be configured to perform the boron diffusion process, LPCVD process, and annealing process of the N-type silicon wafer 1, and the phosphorus diffusion device 7 may be configured to perform the phosphorus diffusion process of the N-type silicon wafer 1.

The phosphorus diffusion loading and unloading system 71 of the phosphorus diffusion device 7 is connected to the laser doping loading end 41 of the laser doping device 4. The laser process apparatus of the laser doping device 4 performs laser grooving on the surface without being textured, performs back laser local doping on the grooving region of an N-type silicon wafer 1 after phosphorus diffusion to form the phosphorus heavily doped region 123. The laser process apparatus includes a phosphorus source. The phosphorus source provides phosphorus for the phosphorus heavily doped region 123. The oxidation system 5 is connected to the laser unloading end 42 of the laser doping device 4, the N-type silicon wafer 1 after laser local phosphorus doping is conveyed to the oxidation system 5, and the oxidation system 5 processes the N-type silicon wafer 1 to protect the phosphorus heavily doped region 123.

The oxidation system 5 is connected to the etching device 6. The oxidation processed N-type silicon wafer 1 is conveyed to the etching device 6 for cleaning and etching, a PSG layer, a BSG layer and an amorphous silicon wrap-around plating on the surface of the N-type silicon wafer 1 are removed, thereby solving a problem that laser ablation is easy to form a dead layer or a damaged layer.

The etching device 6 is connected to the oxidation system 5, and the alkali polishing and etching unloading apparatus 66 is connected to the loading and unloading system 31 of the heat treatment system 3. An N-type silicon wafer 1 that has been alkali polished and etched is transferred to the heat treatment system 3 for annealing, and an oxide layer 121 is formed on the back side of the N-type silicon wafer 1.

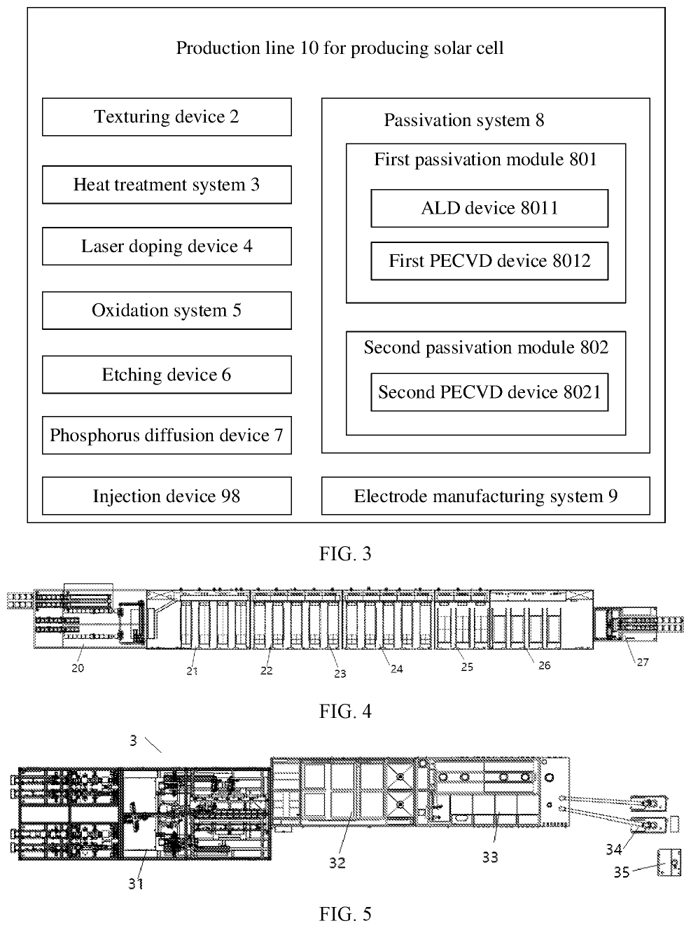

As shown in FIG. 3, the passivation system 8 includes a first passivation module 801 and a second passivation module 802. The first passivation module 801 is configured to perform the passivation layer process. Through the passivation layer process, a passivation layer 111 may be deposited on the surface of the N-type silicon wafer 1 by the passivation system 8. A material of the passivation layer 111 is not limited here. For example, a material of the passivation layer 111 may be AlOₓ. The first passivation module 801 includes an atomic layer deposition (ALD) device 8011 or a first PECVD device 8012. The second passivation module 802 is configured to perform the front film process and the back film process. The front film process is used to deposit a first anti-reflection layer 110 on the front side of the N-type silicon wafer 1, and the back film process is used to deposit a second anti-reflection layer 120 on the back side of the N-type silicon wafer 1. Materials of the first anti-reflection layer 110 and the second anti-reflection layer 120 are not limited here. For example, materials of the first anti-reflection layer 110 and the second anti-reflection layer 120 both may be SiNₓ material. The second passivation module 802 includes a second PECVD device 8021.

In an implementation, the first passivation module 801 and the second passivation module 802 are arranged in the same PECVD device. That is to say, the passivation system 8 includes a PECVD device for simultaneously implementing functions of the first passivation module 801 and the second passivation module 802, that is, the first PECVD device 8012 and the second PECVD device 8021 are a same PECVD device.

In some embodiments, as shown in FIG. 20, the passivation system 8 includes a passivation loading and unloading apparatus 81, a passivation purification table 82, a passivation furnace body 83, a passivation gas cabinet 84 and a passivation vacuum pump 85. The oxidation system 5 is connected to the passivation system 8. An annealed N-type silicon wafer 1 is conveyed to the passivation system 8. The loading and unloading system 31 of the heat treatment system 3 is connected to the passivation loading and unloading device 81. The passivation furnace body 83 is configured to passivate the front side of the N-type silicon wafer 1, deposit the passivation layer 111 and the first anti-reflection layer 110 to reduce front reflection, increase carrier lifetime, and improve current. The passivation furnace body 83 is further configured to grow a second anti-reflection layer 120 on the back side of the N-type silicon wafer 1.

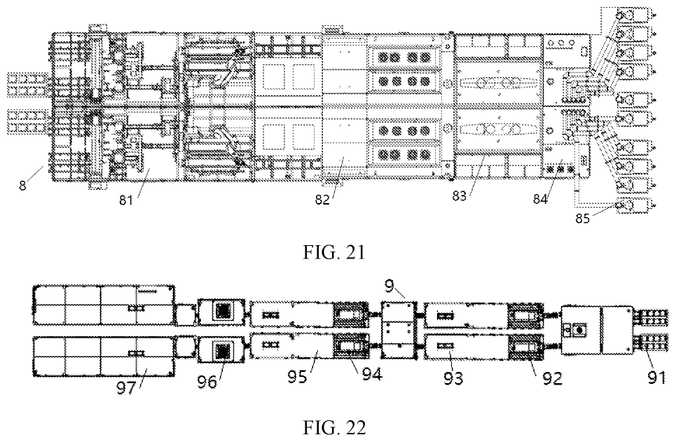

As shown in FIG. 21, the electrode manufacturing system 9 includes an electrode manufacturing loading apparatus 91, a first electrode manufacturing apparatus 92, an electrode manufacturing drying apparatus 93, a second electrode manufacturing apparatus 94, an electrode manufacturing sintering apparatus 95, an electrode manufacturing detecting apparatus 96, and an electrode manufacturing sorting apparatus 97. The passivation loading and unloading apparatus 81 of the passivation system 8 is connected to the electrode manufacturing loading apparatus 91. The passivation system 8 is further configured to convey an N-type silicon wafer 1 processed by the passivation system 8 to the electrode manufacturing loading apparatus 91. The electrode manufacturing system 9 is configured to perform a preparation process of electrodes on two sides of the N-type silicon wafer to form the solar cell. The first electrode manufacturing apparatus 92 is configured to prepare a back electrode 12 on the N-type silicon wafer. The second electrode manufacturing apparatus 94 is configured to prepare a front electrode 11 on the N-type silicon wafer 1. The electrode manufacturing sintering apparatus 95 is configured to sinter the N-type silicon wafer after the electrodes are manufactured into a finished solar cell. The electrode manufacturing detecting apparatus 96 and the electrode manufacturing sorting apparatus 97 are configured to remove an unqualified finished solar cell from the finished solar cell. The electrode manufacturing process may include a screen printing process or an imprinting process. The front electrode 11 includes a plurality of main gates and a plurality of fine gates.

The N-type silicon wafer 1 processed by passivation system 8 is conveyed to the lectrode manufacturing loading apparatus 91. The first electrode manufacturing apparatus 92 prepares the back electrode 12 on the N-type silicon wafer 1. The second electrode manufacturing apparatus 94 prepares the front electrode 11 on the N-type silicon wafer 1. Then the N-type silicon wafer 1 is sintered into the finished solar cell by the electrode manufacturing sintering apparatus 95. After the N-type silicon wafer 1 is sintered, the electrode manufacturing detecting apparatus 96 and the electrode manufacturing sorting apparatus 97 are configured to remove an unqualified finished solar cell from the finished solar cell.

In some embodiments, the production line 10 for producing the solar cell further includes an injection device 98. The injection device 98 is configured to inject a carrier into the solar cell. Anti-degradation performance of the solar cell may be improved by injecting the carrier into the solar cell. The injection device 98 may be a device in a related art, and the injection device 98 may be arranged separately. Optionally, the injection device 98 is connected to the electrode manufacturing sorting apparatus 97. In an implementation, the injection device is an electrical injection device. In another implementation, the injection device is an optical injection device.

In some embodiments, a function of the injection device 98 may alternatively be implemented through another device. For example, the electrode manufacturing sintering apparatus 95 of the electrode manufacturing system 9 is further configured to inject a carrier into solar cell during a sintering process.

The electrical injection device is connected to the electrode manufacturing sorting apparatus 97, and the carrier is injected into the solar cell through a electric injection method to achieve hydrogen passivation.

The present application further provides a method for producing a solar cell by using the aforementioned production line 10 for producing the solar cell. As shown in FIG. 2, the method includes the following steps.

Step 1, Cleaning and texturing: cleaning an N-type silicon wafer 1 in a solution, forming a texture structure on the surface of the N-type silicon wafer, and removing a surface damage layer, a cutting line mark, and a metal ion.

Step 2, Boron diffusion: placing a cleaned N-type silicon wafer 1 in a carrier and pushing the carrier into a boron diffusion process furnace tube for boron diffusion, to form a boron doped region 112.

Optionally, Step 3, Laser dopping: performing laser local doping on a textured surface of an N-type silicon wafer after boron diffusion, to form a boron heavily doped region 113.

Optionally, Step 4, Oxidation: performing an oxidation process an N-type silicon wafer 1 after laser doping, to protect the boron heavily doped region 113.

Step 5, Etching and polishing: removing a BSG layer on a surface of a back side of the N-type silicon wafer 1, and chemically polishing the back side of the N-type silicon wafer 1.

Step 6, LPCVD: growing an oxide layer 121 and an amorphous silicon layer on a surface of the N-type silicon wafer 1. For example, the oxide layer 121 may include an oxide tunneling layer (SiO₂). For example, the amorphous silicon layer may include an intrinsic amorphous silicon layer.

Step 7, Phosphorus diffusion: pushing a LPCVD processed N-type silicon wafer into a phosphorus diffusion device for multiple phosphorus diffusion to form multiple layers of phosphorus doped region 122 on the back side, and performing a post-oxidation treatment on an N-type silicon wafer after phosphorus diffusion, so that a phosphorus-rich layer is formed on the back side of the N-type silicon wafer. For example, the phosphorus layer may include a phosphorus doped polycrystalline silicon layer.

Step 8, Laser dopping: performing laser local doping on the back side of the N-type silicon wafer after phosphorus diffusion, to form a phosphorus heavily doped region 123.

In some implementations, either a first PECVD device or a second PECVD device may be configured to perform Step 6 and Step 7, sequentially growing the oxide layer 121 and the phosphorus-rich layer. Optionally, after a step: growing an oxide layer 121, an amorphous silicon layer, and a phosphorus-rich layer on the surface of the N-type silicon wafer 1 by the PECVD device, the method further includes: performing an annealing process on the N-type silicon wafer 1. The annealing process may be performed through an annealing device or through the boron diffusion apparatus mentioned above.

Optionally, Step 9, Oxidation: performing an oxidation process on an N-type silicon wafer after laser dopping, to protect the phosphorus heavily doped region 123.

Step 10, Etching and polishing: removing a BSG layer, a PSG layer, and an amorphous silicon wrap-around plating on a surface of the N-type silicon wafer 1.

Optionally, Step 11, Annealing: executing an annealing process, and setting step 11 after step 10 to prepare for passivation of the N-type silicon wafer 1 and improve passivation effect.

Step 12, Passivation system processing: passivating the front side of N-type silicon wafer 1 to deposit a passivation layer 111 and a first anti-reflection layer 110 by Passivation System 8, so that front reflection is reduced, lifetime of the carrier is increased, and a current is improved; and growing a second anti-reflection layer 120 on the back side of the N-type silicon wafer 1.

Step 13, Electrode manufacturing process: performing a preparation process of electrodes on two sides of the surface of the N-type silicon wafer 1 by the electrode manufacturing system 9.

Optionally, Step 14, Injection process: injecting a carrier into the solar cell through electrical injection or optical injection by the injection device 98, so that hydrogen passivation is achieved.

Optionally, the injection device 98 injects the carrier into the solar cell through light injection to achieve hydrogen passivation. Optionally, after a step: injecting a carrier into the solar cell through optical injection by the injection device 98, the method further includes: performing an annealing process on the N-type silicon wafer 1.

The present application provides a production line 10 for producing the solar cell, and cleaning and texturing, boron diffusion, etching and polishing, LPCVD, phosphorus diffusion, laser dopping, etching and polishing, passivation system processing, electrode manufacturing process, and injection process are sequentially performed on an N-type silicon wafers 1. Through adding a heat treatment system and an etching device, a production line for a passivated pmitter and rear cell with selective emitter (PERC-SE) cell is greatly adapted and utilized, with almost no waste of devices of the production line for the PERC-SE cell, and lifecycle of the production line for the PERC cell is extended. The present application further adds a cleaning process and adopts a multi-layer phosphorus diffusion deposition method after the laser dopping process, so that a problem of insufficient phosphorus source for laser ablation and formation of a dead layer or a damaged layer during laser ablation is solved. The present application refines and decomposes the phosphorus-doped region structure, adds a phosphorus heavily doped region, so that phosphorus doping effect may be optimized. The phosphorus heavily doped region is subdivided, and the dead layer or the damaged layer formed by laser ablation is removed, so that Ohmic contact becomes better, and a contact resistance between an electrode and the heavily doped region is reduced, thereby reducing the amount of grid lines and lowering costs.

The carrier mentioned above can be a quartz boat, or a boat made of other materials, such as a boat made of silicon carbide material.

What is claimed is:

1. A production line for producing a solar cell, applied to manufacturing an N-type silicon wafer into a solar cell, comprising:
a texturing device, configured to perform a texturing process of the N-type silicon wafer;
a heat treatment system, configured to perform a boron diffusion process and a low pressure chemical vapor deposition (LPCVD) process of the N-type silicon wafer;
a phosphorus diffusion device, configured to perform a phosphorus diffusion process on the N-type silicon wafer, to dope intrinsic amorphous silicon layer on a back side of the N-type silicon wafer with phosphorus;
an etching device, configured to perform an etching process of the N-type silicon wafer;
a passivation system, configured to perform a passivation layer process, a front film process and a back film process of the N-type silicon wafer; and
an electrode manufacturing system, configured to perform a preparation process of electrodes on two sides of the N-type silicon wafer to form the solar cell.

2. The production line for producing the solar cell according to claim 1, wherein the passivation system comprises:
a first passivation module, configured to perform the passivation layer process, wherein the first passivation module comprises an atomic layer deposition (ALD) device or a first plasma enhanced chemical vapor deposition (PECVD) device; and
a second passivation module, configured to perform the front film process and the back film process, wherein the second passivation module comprises a second PECVD device.

3. The production line for producing the solar cell according to claim 1, further comprising:
a laser doping device, configured to perform laser local boron doping on a front side of the N-type silicon wafer to form a boron heavily doped region, and perform laser local phosphorus doping on the back side of the N-type silicon wafer to form a phosphorus heavily doped region; and
an oxidation system, configured to perform an oxidation process of the N-type silicon wafer to protect the boron heavily doped region and the phosphorus heavily doped region.

4. The production line for producing the solar cell according to claim 3, wherein the etching device is further configured to perform an alkali polishing process of the N-type silicon wafer.

5. The production line for producing the solar cell according to claim 4, wherein
the texturing device comprises a texturing loading apparatus, a texturing pre-cleaning tank, a texturing apparatus, a texturing post-cleaning tank, a texturing pickling tank, a texturing pre-dehydration tank, a texturing drying tank, and a texturing unloading apparatus connected in sequence;
the texturing loading apparatus is configured to move the N-type silicon wafer to the texturing pre-cleaning tank for cleaning;
the texturing pre-cleaning tank is configured to remove an impurity on a surface of the N-type silicon wafer;
the texturing apparatus is configured to form a texture structure on the surface of the N-type silicon wafer by using an alkaline solution;
the texturing post-cleaning tank is configured to clean the N-type silicon wafer after the texture structure is formed on the surface of the N-type silicon wafer to remove an impurity on the surface of the N-type silicon wafer;
the texturing pickling tank is configured to pickle the N-type silicon wafer with acid to neutralize the alkaline solution and remove a metal ion from the surface of the N-type silicon wafer;
the texturing pre-dehydration tank is configured to dehydrate the N-type silicon wafer after the N-type silicon wafer is pickled;
the texturing drying tank is configured to dry the N-type silicon wafer after the N-type silicon wafer is dehydrated; and
the texturing unloading apparatus is configured to convey the N-type silicon wafer completing the texturing process to the heat treatment system for further processing.

6. The production line for producing the solar cell according to claim 5, wherein
the heat treatment system comprises a loading and unloading system, a carrier conveying and purifying system, and a furnace tube system;
the texturing unloading apparatus of the texturing device is connected to the loading and unloading system of the heat treatment system, and the loading and unloading system comprises a loading wafer-guiding assembly, a unloading wafer-guiding assembly, a wafer-guiding circulation conveying mechanism, a silicon wafer grabbing apparatus, a loading carrying mechanism, a unloading carrying mechanism and a carrier circulation mechanism;
the carrier conveying and purifying system comprises a carrier carrying system, a carrier pushing system, a purifying and cooling system, a transmission system and a purification table frame;
the furnace tube system comprises a furnace tube rack and a process furnace tube; and
the transmission system is connected to both the carrier circulation mechanism and the carrier carrying system, and is configured to perform a circulation of a carrier between the loading and unloading system and the carrier conveying and purifying system; the carrier pushing system is connected to the process furnace tube, and is configured to perform a circulation of the carrier between the carrier conveying and purifying system and the furnace tube system; the carrier is configured to circulate between the loading and unloading system, the carrier conveying and purifying system and the furnace tube system; the N-type silicon wafer is horizontally placed inside the carrier; and the process furnace tube comprises a LPCVD process furnace tube, a boron diffusion process furnace tube and an annealing process furnace tube, the LPCVD process furnace tube is configured to perform the LPCVD process, the boron diffusion process furnace tube is configured to perform the boron diffusion process, and the annealing process furnace tube is configured to execute an annealing process.

7. The production line for producing the solar cell according to claim 6, wherein the heat treatment system is further configured to perform the annealing process of the N-type silicon wafer.

8. The production line for producing the solar cell according to claim 6, wherein
the loading and unloading system comprises a wafer guiding apparatus, and the wafer guiding apparatus comprises the loading wafer-guiding assembly, the unloading wafer-guiding assembly, the wafer-guiding circulation conveying mechanism, the loading carrying mechanism, the unloading carrying mechanism and the carrier circulation mechanism;
the silicon wafer grabbing apparatus comprises a six-axis robot and a silicon wafer grabbing and releasing mechanism, the silicon wafer grabbing and releasing mechanism is configured to control suction to the N-type silicon wafer and turn-over of the N-type silicon wafer, and the six-axis robot is configured to control movement of the N-type silicon wafer through the silicon wafer grabbing and releasing mechanism;
the loading and unloading system further comprises a silicon wafer loading system and a silicon wafer unloading system, wherein the silicon wafer loading system comprises the loading wafer-guiding assembly, the silicon wafer grabbing apparatus, the loading carrying mechanism and the carrier circulation mechanism, and the silicon wafer unloading system comprises the unloading wafer-guiding assembly, the silicon wafer grabbing apparatus, the unloading carrying mechanism and the carrier circulation mechanism;
the carrier carrying system, the carrier pushing system and the transmission system are installed inside the purification table frame, and the purifying and cooling system is located outside the purification table frame;
the transmission system is configured to transfer a carrier loaded with an unprocessed N-type silicon wafer located in the loading and unloading system to the carrier carrying system, and transfer a carrier loaded with a processed N-type silicon wafer to the loading and unloading system, so as to perform a carrier interaction between the carrier carrying system and the loading and unloading system;
the carrier carrying system is configured to move the carrier loaded with the unprocessed N-type silicon wafer to the carrier pushing system;
the carrier pushing system is configured to move the carrier loaded with the unprocessed N-type silicon wafer to the furnace tube system for processing, and the carrier pushing system is further configured to move out the carrier loaded with the processed N-type silicon wafer and move the carrier loaded with the processed N-type silicon wafer to the transmission system through the carrier carrying system; and
the purifying and cooling system is configured to purify gas of the carrier conveying and purifying system.

9. The production line for producing the solar cell according to claim 6, wherein
the laser doping device comprises a laser doping loading end, a laser processing cavity, and a laser unloading end; and
the loading and unloading system of the heat treatment system is connected to the laser doping loading end of the laser doping device, a laser process apparatus is provided in the laser processing cavity, and the laser process apparatus is configured to perform laser grooving on a textured surface, perform front laser local doping on a grooving region of an N-type silicon wafer after boron diffusion to form the boron heavily doped region, perform laser grooving on a surface without being textured and perform front laser local doping on a grooving region of an N-type silicon wafer after phosphorus diffusion to form the phosphorus heavily doped region.

10. The production line for producing the solar cell according to claim 9, wherein the oxidation system comprises an oxidation loading and unloading apparatus, an oxidation purification table, an oxidation furnace body and an oxidation gas cabinet, and the laser unloading end of the laser doping device is connected to the oxidation loading and unloading apparatus of the oxidation system.

11. The production line for producing the solar cell according to claim 10, wherein the etching device comprises an alkali polishing and etching loading apparatus, an alkali polishing and etching protection apparatus, an alkali polishing and etching performing apparatus, an alkali polishing and etching alkali washing apparatus, an alkali polishing and etching pickling apparatus and an alkali polishing and etching unloading apparatus, the oxidation loading and unloading apparatus of the oxidation system is connected to the alkali polishing and etching loading apparatus of the etching device, and the etching device cleans and etches the N-type silicon wafer.

12. The production line for producing the solar cell according to claim 11, wherein
the phosphorus diffusion device comprises a phosphorus diffusion loading and unloading system, a phosphorus diffusion purification table, a phosphorus diffusion furnace cabinet, a phosphorus diffusion gas cabinet and a phosphorus diffusion phosphorus source cabinet; and
the loading and unloading system of the heat treatment system is connected to the phosphorus diffusion loading and unloading system of the phosphorus diffusion device, and the phosphorus diffusion loading and unloading system of the phosphorus diffusion device is connected to the laser doping loading end of the laser doping device.

13. The production line for producing the solar cell according to claim 6, wherein
the passivation system comprises a passivation loading and unloading apparatus, a passivation purification table, a passivation furnace body, a passivation gas cabinet and a passivation vacuum pump; and
the loading and unloading system of the heat treatment system is connected to the passivation loading and unloading apparatus, and the passivation furnace body is configured to passivate the front side of the N-type silicon wafer, deposit an AlOₓ passivation layer and a SiNₓ layer or a SiOₓN_{y} layer, and grow a SiNₓ layer or a SiOₓN_{y} layer on the back side of the N-type silicon wafer.

14. The production line for producing the solar cell according to claim 13, wherein the electrode manufacturing system comprises an electrode manufacturing loading apparatus, a first electrode manufacturing apparatus, an electrode manufacturing drying apparatus, a second electrode manufacturing apparatus, an electrode manufacturing sintering apparatus, an electrode manufacturing detecting apparatus, and an electrode manufacturing sorting apparatus;
the passivation loading and unloading apparatus of the passivation system is connected to the electrode manufacturing loading apparatus, and the passivation system is further configured to convey an N-type silicon wafer processed by the passivation system to the electrode manufacturing loading apparatus;
the first electrode manufacturing apparatus is configured to prepare a back electrode on the N-type silicon wafer;
the second electrode manufacturing apparatus is configured to prepare a front electrode on the N-type silicon wafer;
the electrode manufacturing sintering apparatus is configured to sinter the N-type silicon wafer after the electrodes are manufactured into a finished solar cell; and
the electrode manufacturing detecting apparatus and the electrode manufacturing sorting apparatus are configured to remove an unqualified finished solar cell from the finished solar cell.

15. The production line for producing the solar cell according to claim 14, wherein the electrode manufacturing sintering apparatus is further configured to inject a carrier into the solar cell during a sintering process.

16. The production line for producing the solar cell according to claim 14, further comprising an injection device, connected to the electrode manufacturing sorting apparatus and configured to inject a carrier into the solar cell.

17. The production line for producing the solar cell according to claim 13, wherein
the passivation layer process comprises depositing the AlOₓ passivation layer on the front side of the N-type silicon wafer;
the front film process comprises depositing the SiNₓ layer or the SiOₓN_{y} layer on the front side of the N-type silicon wafer; and
the back film process comprises depositing the SiNₓ layer or the SiOₓN_{y} layer on the back side of the N-type silicon wafer.
